(19) United States
(12) Patent Application Publication
(10) Pub. No.: US 2016/0097812 A1
(43) Pub. Date: Apr. 7, 2016

(54) SEMICONDUCTOR PACKAGE

(71) Applicant: SK hynix Inc., Icheon-si Gyeonggi-do (KR)

(72) Inventor: Ki Up KIM, Cheongju-si Chungcheongbuk-do (KR)

(21) Appl. No.: 14/575,846

(22) Filed: Dec. 18, 2014

(30) Foreign Application Priority Data
Oct. 7, 2014 (KR) 10-2014-0135009

(51) Int. Cl. G01R 31/317; G01R 31/30

(52) U.S. Cl. CPC G01R 31/31715; G01R 31/30

(57) ABSTRACT

A semiconductor package may include a probe circuit unit configured to be driven by buffering a signal received from a probe pad during probe testing, a bump circuit unit configured to buffer a signal received from a bump pad, and a power-source selection unit configured to change a level of an internal power-supply voltage applied to the probe circuit unit in response to a test-mode signal.

### CROSS-REFERENCE TO RELATED APPLICATION

This application claims priority based upon Korean patent application No. 10-2014-0135009, filed on Oct. 7, 2014, the disclosure of which is hereby incorporated in its entirety by reference herein.

### BACKGROUND

1. Technical Field

Various embodiments generally relate to a semiconductor package, and more particularly to a technology for improving current screen efficiency during probe testing.

2. Related Art

In recent times, electronic industries have been rapidly developed to implement low-priced products having lighter weights, smaller sizes, higher speeds, multifunctional abilities, higher performances, and greater reliability. One of the important technologies in goal attainment of the product design is a package assembly technology.

The package assembly technology protects a semiconductor chip having an integrated circuit (IC) from external environments through wafer assembly processing, and enables semiconductor chips to be easily populated on a substrate, such that it can guarantee the operation reliability of the semiconductor chips.

In order to manufacture a conventional package, a wafer is divided into a plurality of semiconductor chips, and each semiconductor chip is packaged. However, the packaging process includes a large number of unit processes, i.e., chip attachment, wire bonding, molding, trimming/forming, etc.

The conventional package formation method in which each packaging process must be performed for each semiconductor chip requires a very long packaging consumption time for all semiconductor chips when considering the number of semiconductor chips obtained from one wafer.

As a result, a Wafer Level Chip Scale Package technology has recently been proposed, which does not perform the assembling process on the condition that a wafer is divided into a plurality of semiconductor chips, performs rearrangement at a wafer state, forms an external connection terminal shaped in a ball, and isolates each semiconductor chip, resulting in formation of a plurality of semiconductor chips.

A method for forming the wafer level chip scale package includes forming a wafer, forming a first insulation film exposing a bonding pad on a semiconductor chip having a bonding pad, and forming rearrangement lines respectively coupled to the bonding pads over the first insulation film.

Thereafter, a second insulation film is formed over the first insulation film and the rearrangement line in a manner that some parts of the rearrangement line are exposed, and the external connection terminal such as a solder ball is attached on the exposed rearrangement line. Subsequently, the wafer including the external connection terminal is cut in a chip level, so that fabrication of the wafer level chip scale package is completed.

A system on chip (SoC) is formed by stacking a plurality of chips through a Through Silicon Via (TSV), or a multi chip package (MCP) is formed by stacking a plurality of memory chips through a TSV.

A pad for use in a semiconductor device is coupled to external lines. However, the MCP is formed using a smaller-sized bump pad than a general pad.

If the bump pad is very small in size, it is impossible to perform probing of the bump pad using a probe pin during probe testing needed for memory testing. Accordingly, other probe pads are additionally manufactured to perform testing.

In this case, a pad using the bump pad is different from a pad using the pad for probe testing. Thus, an additional buffer for the pad for probe testing and a circuit such as a driver for signal transmission are additionally needed.

The pad for probe testing may receive a signal for testing from an external part. The pad for probe testing is additionally required for probe testing, such that high input loads are established.

Therefore, an additional circuit for probe testing operates during the testing operation, resulting in consumption of a current. The higher the current component, the lower the current screen efficiency of an actual product.

Specifically, if the input circuit frequently operates during a high-frequency operation, the current component of the probe testing circuit increases, so that it becomes difficult to perform current screening during the actual operation.

### BRIEF SUMMARY

In accordance with an embodiment, a semiconductor package may include a probe circuit unit configured to be driven by buffering a signal received from a probe pad during probe testing. The semiconductor package may include a bump circuit unit configured to buffer a signal received from a bump pad, and a power-source selection unit configured to change a level of an internal power-supply voltage applied to the probe circuit unit in response to a test-mode signal.

In accordance with an embodiment, a semiconductor package may include a data pad configured to receive data during probe testing, and a first probe test buffer configured to buffer data received from the data pad in response to an internal power-supply voltage. The semiconductor package may include a first probe test driver configured to drive data received from the first probe test buffer in response to the internal power-supply voltage, a bump circuit unit configured to buffer a signal received from a bump pad, and a power-source selection unit configured to change a level of the internal power-supply voltage applied to the first probe test buffer and the first probe test driver in response to a test-mode signal.

In accordance with an embodiment, a semiconductor package may include a probe circuit unit configured to receive data and an address through pads, a bump circuit unit coupled with the probe circuit unit and configured to receive data and an address through bump pads, and a power source selection unit configured to provide a first power-supply voltage to the probe circuit unit and a second power-supply voltage to the bump circuit unit. The first power-supply voltage may be different from the second power-supply voltage in response to a test-mode signal received by the power source selection unit.

### BRIEF DESCRIPTION OF THE DRAWINGS

FIG. 1 is a block diagram illustrating a representation of a semiconductor package according to an embodiment.

FIG. 2 is a detailed circuit diagram illustrating a representation of a power-source selection unit of FIG. 1.

FIG. 3 illustrates a block diagram of an example of a representation of a system employing the semiconductor package in accordance with the embodiments discussed above with relation to FIGS. 1-2.

### DETAILED DESCRIPTION

Reference will now be made in detail to the various embodiments, examples of which are illustrated in the accompanying drawings. Wherever possible, the same reference numbers are used throughout the drawings to refer to the same or like portions. In the following description of the various embodiments, a detailed description of related known configurations or functions incorporated herein may be omitted for clarity of the subject matter.

Various embodiments may be directed to providing a semiconductor package which substantially obviates one or more problems due to limitations or disadvantages of the related art.

Various embodiments may relate to a semiconductor package configured to use a bump pad, which converts a power-supply voltage of the probe testing circuit into another voltage during a test mode, such that the current screen efficiency may be improved during the probe testing.

Embodiments may relate to Double Data Rate Synchronous DRAM (DDR SDRAM) and semiconductor devices in various technical fields to meet the demand of users, and a representative one of the technical fields is a packaging technology. Embodiments may utilize a technology for packaging the semiconductor device relating to a Multi Chip Package (MCP).

The MCP refers to a single chip comprised of a plurality of semiconductor chips. The MCP may increase memory capacity using a plurality of memory chips each having a memory function, or may improve a desired performance using semiconductor integrated circuits (ICs) having different functions.

For reference, MCP may be classified into a single-layered MCPs and a multi-layered MCP according to MCP construction. The single-layered MCP is formed of a plurality of semiconductor chips being arranged in parallel on a plane, and the multi-layered MCP is formed of a stacked structure of semiconductor chips.

Assuming for example that a plurality of semiconductor ICs is implemented by a multi-layered MCP, the multi-layered MCP may be implemented by wire-bonding of input/output (I/O) terminals of individual semiconductor chips. However, if the multi-layered MCP is implemented through such wire-bonding, the multi-layered MCP is vulnerable to high speed and noise, and a chip-on-chip packaging technology may be used.

The chip-on-chip packaging technology serving as a technology for directly interconnecting a plurality of semiconductor chips through a bump and a Through Silicon Via (TSV) can vertically stack a plurality of semiconductor ICs without using wires.

It may be possible to perform a high-speed operation using the chip-on-chip packaging technology as well as to reduce power consumption. In addition, the chip-on-chip packaging technology may also minimize the entire MCP area.

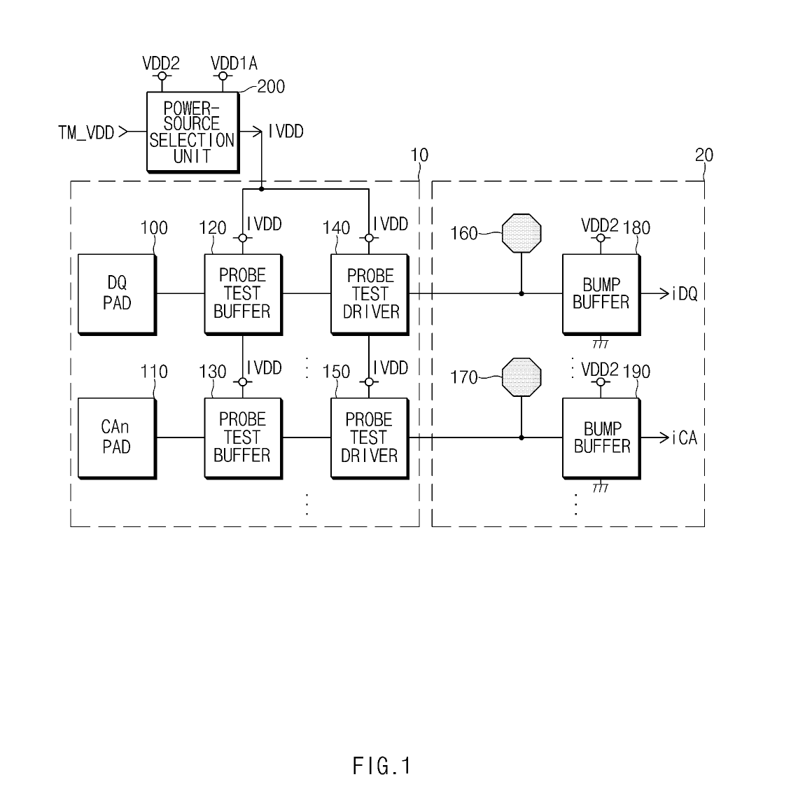

FIG. 1 is a block diagram illustrating a representation of a semiconductor package according to an embodiment.

Referring to FIG. 1, the semiconductor package may include a data (DQ) pad 100, an address (CAn) pad 110, and probe test buffers (120, 130). The semiconductor package may include probe test drivers (140, 150), bump pads (160, 170), bump buffers (180, 190), and a power-source selection unit 200.

For example, the data (DQ) pad 100, the address (CAn) pad 110, the probe test buffers (120, 130), and the probe test drivers (140, 150) may correspond to a probe circuit unit 10. For example, the bump pads (160, 170) and the bump buffers (180, 190) may correspond to a bump circuit unit 20.

The data (DQ) pad 100 may be a data input pad for receiving data during, for example, probe testing. The address (CAn) pad 110 may be an address input pad for receiving addresses during, for example, the probe testing. In accordance with an embodiment, a command address is input to the address (CAn) pad 110.

The semiconductor memory device stores data therein, and outputs the stored data. The semiconductor memory device performs testing at a wafer state, and normal semiconductor memory devices are packaged and produced as a product.

The semiconductor package receives an external voltage from an external part or a device external to the semiconductor package, and generates an internal voltage according to the type of purpose used. The semiconductor package performs testing so that it can determine a normal or abnormal state.

When fabricating the semiconductor package, a testing process may be performed to determine whether the semiconductor device normally operates. Using this testing process while fabricating may result in an increase in production efficiency. The testing process of the semiconductor device may include applying an electric signal to the pad of the semiconductor device, and determining whether output data is normal.

The testing processes of the semiconductor package may be classified into a test for monitoring an internal voltage and a test for directly receiving an internal voltage from an external part of a circuit configured to use the internal voltage.

As described above, if the internal voltage is monitored or if a voltage is directly received from the external part, the data (DQ) pad 100 acting as a probing pad and the address (CAn) pad 110 may be used. The data (DQ) pad 100 and the address (CAn) pad 110 may be used for signal transmissions when, for example, the semiconductor package of a wafer state is tested. During the probe testing, a test executer may perform probing of the probe pads (100, 110) using a probe pin coupled to the probe test card so as to perform a variety of testing operations.

For convenience of description and better understanding, the pad for probe testing according to the embodiments may include the data (DQ) pad 100 and the address (CAn) pad 110.

However, the scope or spirit of the probe testing pad according to the various embodiments are not limited thereto, and the probe testing pad of the embodiments may further include, for example, a command input pad, an external-power-source pad, a ground-power-source pad, a test pad for receiving signals mandatorily received from an external part so as to perform testing, and a pad for monitoring an internal operation or internal voltage of the semiconductor memory, etc. For various usages and purposes, external signals may be applied to each chip through the pad.

The probe test buffer 120 may perform buffering of data received from the data (DQ) pad 100, and may output the buffered data to the probe test driver 140. The probe test buffer 130 may perform buffering of addresses received from the address pad 110, and may output the resultant addresses to the test driver 150. In an embodiment, the probe test buffers (120, 130) may operate with an internal power-supply voltage (IVDD) received from the power-source selection unit 200.

The probe test driver 140 may drive data received from the probe test buffer 120 and output the data to the bump pad 160. The probe test driver 150 may drive data received from the test buffer 130, and may output the data to the bump pad 170. In an embodiment, the probe test drivers (140, 150) may operate with the internal power-supply voltage IVDD received from the power-source selection unit 200.

The bump pad 160 may receive data and output the data to the bump buffer 180. The bump pad 170 may receive an address and output the address to the bump buffer 190. In accordance with an embodiment, a command address may be input to the address pad 110 for convenience of description and better understanding. When the bump pads (160, 170) are mounted to a substrate of the semiconductor package or stacked on another semiconductor chip, the bump pads (160, 170) may, for example, be used for signal transmission.

The bump buffer 180 may perform buffering of data received from the bump pad 160, and may output internal data (iDQ). The bump buffer 190 may perform buffering of the address received from the bump pad 170, and may output an internal address (iCA). In an embodiment, the bump buffers (180, 190) may operate by a power-supply voltage VDD2.

It may be impossible for the Multi Chip Package (MCP) to perform probing of the bump pads (160, 170) using the bump pads (160, 170) smaller in size than a general pad. Therefore, the semiconductor package may include a data (DQ) pad 100 for probe testing, an address (CAn) pad 110, probe test buffers (120, 130), and probe test drivers (140, 150).

However, if many probe pads, such as the data (DQ) pad 100 and the address (CAn) pad 110, are arranged to perform probe testing, a testing time may increase. Since the number of channels provided from the testing device may be limited, it may be preferable that the number of pads needed for testing be reduced to simultaneously test as many dies as possible.

A distance between the probe pad (100 or 110) and the bump pad (160 or 170) may be very long, and signals of a single probe pad may be applied to a plurality of bump pads (160, 170).

Therefore, in order to transmit signals being input to both the data (DQ) pad 100 and the address (CAn) pad 110 to the bump pads (160, 170), the probe test buffers (120, 130) and the probe test drivers (140, 150) may be used.

It may be possible for the bump for use in the chip-on-chip packaging technology to have a very small size. However, during the testing operation based on the probe pin, it may be very difficult for the probe pin to contact a small-sized bump. Therefore, in order to normally perform the probe testing operation, the probe pad larger in size than the bump pad may be additionally designed.

A semiconductor device may be configured to stack semiconductor chips using through silicon via (TSV). The semiconductor device may include, for example, the bump pads (160, 170) as the I/O pads.

That is, a plurality of chips may be coupled to the semiconductor package through a TSV, and the bump pads (160, 170) may be configured to perform signal transmissions between TSVs of respective chips. The semiconductor package may be unable to endure the load of the probe testing device when only using the bump pads (160, 170). Therefore, a separate circuit for probe testing and the pads (100, 110) may be needed.

If the probe circuit unit 10 and the bump circuit unit 20 are operated at the same time using the same power source, a current of the probe circuit unit 10 may be added. Accordingly, a current needed for testing may be higher than that of the actual operation, and a current screen efficiency needed for such testing may be less than that of the actual operation.

Therefore, an embodiment may selectively control a power-supply voltage applied to the probe circuit unit 10 in, for example, a test mode, and in response to an internal power-supply voltage IVDD generated from the power-source selection unit 200.

For example, the power-source selection unit may select any one of a power-supply voltage VDD2 and a power-supply voltage VDD1A in response to a test-mode signal (TM_VDD), and may output the selected one as an internal power-supply voltage IVDD of the probe circuit unit 10. In an embodiment, the power-supply voltage VDD2 has the same power level or substantially the same power level as in a power-supply voltage applied to the bump circuit unit 20.

The power-supply voltage VDD1A may have a power source separated from the power-supply voltage VDD2, and the power-supply voltage VDD1A may have a voltage level different from a power-supply voltage (VDD2) level. The power-supply voltage VDD1A according to the embodiment may be higher in level than the other power-supply voltage VDD2.

The power-source selection unit 200 may deactivate the test-mode signal (TM_VDD) to a first level (e.g., a low level) during a general test mode. Accordingly, the power-supply voltage VDD2 is supplied, as the internal power-supply voltage IVDD, to the probe circuit unit 10.

In these examples, the probe circuit unit 10 and the bump circuit unit 20 are driven by the same power-supply voltage (VDD2) level. In other words, during the general test mode, the probe circuit 10 and the bump circuit unit 20 are driven by the same power-supply voltage (VDD2) level.

In contrast, the power-source selection unit 200 may activate the test-mode signal (TM_VDD) to a second level (e.g., a high level) during the current test mode. Therefore, the power-supply voltage (VDD1A) is supplied, as the internal power-supply voltage IVDD, to the probe circuit unit 10.

In these examples, the probe circuit unit 10 and the bump circuit unit 20 are driven by different voltage levels. That is, during the current test mode, the probe circuit unit 10 and the bump circuit unit 20 are driven by different power-supply voltages VDD1A.

During the current test mode, the probe circuit unit 10 uses a power-supply voltage different from that of the bump circuit unit 20, such that the probe circuit unit 10 measures the current using the different power-supply voltage. As a result, only the substantially flowing current other than a current flowing in the probe circuit unit 10 is measured so that the current screen efficiency can be improved.

The above-mentioned embodiments may be applied to a semiconductor package capable of using a heterogeneous power-supply voltage, may separate the power-supply voltage VDD1A and the power-supply voltage VDD2 from each other according to whether the test-mode signal (TM_VDD) is applied, and may test the two power-supply voltages (VDD1A and VDD2).

That is, when a current corresponding to the power-supply voltage VDD1A is tested, the test-mode signal (TM_VDD) may be activated and the current may then be measured. In addition, during the general test mode corresponding to the power-supply voltage VDD2, the test-mode signal (TM_VDD) may be deactivated and the current may then be measured.

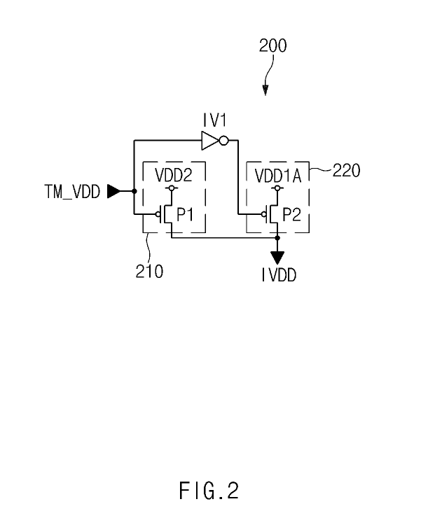

FIG. 2 is a detailed circuit diagram illustrating a representation of the power-source selection unit 200 of FIG. 1.

Referring to FIG. 2, the power-source selection unit 200 may include an inverter IV1, a first power-source selection unit 210, and a second power-source selection unit 220.

For example, the first power-source selection unit 210 may include a PMOS transistor P1. The PMOS transistor P1 may be coupled between the power-supply voltage (VDD2) input terminal and the internal power-supply voltage (IVDD) output terminal, so that the PMOS transistor P1 may receive the test-mode signal (TM_VDD) through a gate terminal.

The second power-source selection unit 220 may include a PMOS transistor P2. The PMOS transistor P2 may be coupled between the power-supply voltage (VDD1A) input terminal and the internal power-supply voltage (IVDD) output terminal, so that the PMOS transistor P2 may receive the test-mode signal (TM_VDD) inverted by the inverter IV1 through a gate terminal.

During the general test mode, the test-mode signal (TM_VDD) may be deactivated to a low level. Therefore, the PMOS transistor P1 is turned on and the PMOS transistor P2 is turned off, so that the power-supply voltage VDD2 is supplied, as the internal power-supply voltage IVDD, to the probe circuit unit 10.

During the current test mode, the test-mode signal (TM_VDD) may be activated to a high level. Therefore, the PMOS transistor P1 is turned off and the PMOS transistor P2 is turned on, so that the power-supply voltage VDD1A is supplied, as the internal power-supply voltage IVDD, to the probe circuit unit 10.

The chip scale package according to the embodiments may be widely used in small-sized and mobile products, for example, a digital camcorder, a mobile phone, a laptop computer, a memory card, and the like. For example, semiconductor devices (for example, a Digital Signal Processor (DSP), an Application Specific Integrated Circuit (ASIC), a microcontroller, etc.) may be populated into the chip scale package. In addition, the chip scale package in which memory devices (for example, a dynamic random access memory (DRAM), a flash memory, etc.) are populated may rapidly come into widespread use.

As is apparent from the above description, the semiconductor packages configured to use the bump pad according to the embodiments may convert a power-supply voltage of the probe testing circuit into another voltage during the test mode, so that the current screen efficiency may be improved during, for example, the probe testing.

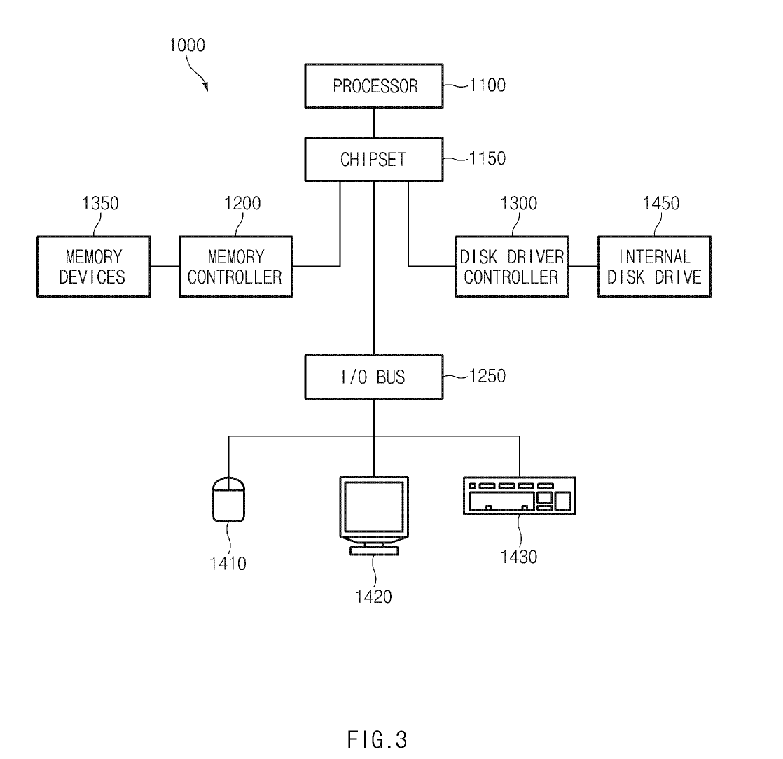

The semiconductor packages discussed above (see FIGS. 1-2) are particular useful in the design of memory devices, processors, and computer systems. For example, referring to FIG. 3, a block diagram of a system employing the semiconductor packages in accordance with the embodiments are illustrated and generally designated by a reference numeral 1000. The system 1000 may include one or more processors or central processing units (“CPUs”) 1100. The CPU 1100 may be used individually or in combination with other CPUs. While the CPU 1100 will be referred to primarily in the singular, it will be understood by those skilled in the art that a system with any number of physical or logical CPUs may be implemented.

A chipset 1150 may be operably coupled to the CPU 1100. The chipset 1150 is a communication pathway for signals between the CPU 1100 and other components of the system 1000, which may include a memory controller 1200, an input/output (“I/O”) bus 1250, and a disk drive controller 1300. Depending on the configuration of the system, any one of a number of different signals may be transmitted through the chipset 1150, and those skilled in the art will appreciate that the routing of the signals throughout the system 1000 can be readily adjusted without changing the underlying nature of the system.

As stated above, the memory controller 1200 may be operably coupled to the chipset 1150. The memory controller 1200 may include at least one semiconductor package as discussed above with reference to FIGS. 1-2. Thus, the memory controller 1200 can receive a request provided from the CPU 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the at least one semiconductor package as discussed above with relation to FIGS. 1-2, the memory devices 1350 may include a plurality of word lines and a plurality of bit lines for defining a plurality of memory cells. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420, and 1430. Further, the I/O bus 1250 may be integrated into the chipset 1150.

The disk drive controller 1450 (i.e., internal disk drive) may also be operably coupled to the chipset 1150. The disk drive controller 1450 may serve as the communication pathway between the chipset 1150 and one or more internal disk drives 1450. The internal disk drive 1450 may facilitate disconnection of the external data storage devices by storing both instructions and data. The disk drive controller 1300 and the internal disk drives 1450 may communicate with each other or with the chipset 1150 using virtually any type of communication protocol, including all of those mentioned above with regard to the I/O bus 1250.

It is important to note that the system 1000 described above in relation to FIG. 3 is merely one example of a system employing the semiconductor packages as discussed above with relation to FIGS. 1-2. In alternate embodiments, such as cellular phones or digital cameras, the components may differ from the embodiments illustrated in FIG. 3.

Those skilled in the art will appreciate that the embodiments may be carried out in other specific ways than those set forth herein without departing from the spirit and essential characteristics of the description. The above embodiments are therefore to be construed in all aspects as illustrative and not restrictive. All changes coming within the meaning and equivalency range of the appended claims are intended to be embraced therein. In addition, it is obvious to those skilled in the art that claims that are not explicitly cited in each other in the appended claims may be presented in combination as an embodiment of the invention or included as a new claim by a subsequent amendment after the application is filed.

Although a number of illustrative embodiments have been described, it should be understood that numerous other modifications and embodiments can be devised by those skilled in the art that will fall within the spirit and scope of the principles of this disclosure. Particularly, numerous variations and modifications are possible in the component parts and/or arrangements which are within the scope of the disclosure, the drawings and the accompanying claims. In addition to variations and modifications in the component parts and/or arrangements, alternative uses will also be apparent to those skilled in the art.

What is claimed is:

1. A semiconductor package comprising:
a probe circuit unit configured to be driven by buffering a signal received from a probe pad during probe testing;
a bump circuit unit configured to buffer a signal received from a bump pad; and
a power-source selection unit configured to change a level of an internal power-supply voltage applied to the probe circuit unit in response to a test-mode signal.

2. The semiconductor package according to claim 1, wherein the power-source selection unit selects any one of a first power-supply voltage and a second power-supply voltage in response to the test-mode signal, and outputs the selected voltage as the internal power-supply voltage.

3. The semiconductor package according to claim 2, wherein the second power-supply voltage is higher in level than the first power-supply voltage.

4. The semiconductor package according to claim 1, wherein:
if the test-mode signal is deactivated, the power-source selection unit outputs a second power-supply voltage as the internal power-supply voltage; and
if the test-mode signal is activated, the power-source selection unit outputs a first power-supply voltage as the internal power-supply voltage.

5. The semiconductor package according to claim 1, wherein:
if the test-mode signal is deactivated, the power-source selection unit provides the same power-supply voltage as that of the bump circuit unit as the internal power-supply voltage; and
if the test-mode signal is activated, the power-source selection unit provides a power-supply voltage different from that of the bump circuit unit as the internal power-supply voltage.

6. The semiconductor package according to claim 1, wherein the probe circuit unit includes a data pad configured to receive data during the probe testing.

7. The semiconductor package according to claim 6, wherein the probe circuit unit further includes:
a first probe test buffer configured to buffer data received from the data pad in response to the internal power-supply voltage.

8. The semiconductor package according to claim 7, wherein the probe circuit unit further includes:
a first probe test driver configured to drive data received from the first probe test buffer in response to the internal power-supply voltage.

9. The semiconductor package according to claim 1, wherein the probe circuit unit includes an address pad configured to receive an address during the probe testing.

10. The semiconductor package according to claim 9, wherein the probe circuit unit further includes:
a second probe test buffer configured to buffer an address received from the address pad in response to the internal power-supply voltage.

11. The semiconductor package according to claim 10, wherein the probe circuit further includes:
a second probe test driver configured to drive an address received from the second probe test buffer in response to the internal power-supply voltage.

12. The semiconductor package according to claim 1, wherein the bump circuit unit includes a first bump pad configured to receive data as an input.

13. The semiconductor package according to claim 12, wherein the bump circuit unit further includes a first bump buffer configured to buffer data received from the first bump pad.

14. The semiconductor package according to claim 13 wherein the first bump buffer outputs internal data after buffering the data.

15. The semiconductor package according to claim 1, wherein the bump circuit unit includes:
a second bump pad configured to receive an address as an input.
a second bump buffer configured to buffer an address received from the second bump pad.

16. The semiconductor package according to claim 15, wherein the second bump buffer outputs an internal address after buffering the address.

17. A semiconductor package comprising:
a data pad configured to receive data during probe testing;
a first probe test buffer configured to buffer data received from the data pad in response to an internal power-supply voltage;
a first probe test driver configured to drive data received from the first probe test buffer in response to the internal power-supply voltage;
a bump circuit unit configured to buffer a signal received from a bump pad; and
a power-source selection unit configured to change a level of the internal power-supply voltage applied to the first probe test buffer and the first probe test driver in response to a test-mode signal.

18. The semiconductor package according to claim 17, wherein the power-source selection unit comprises:
a first power-source selection unit configured to receive a test-mode signal and output a first power-supply voltage; and
a second power-source selection unit configured to receive an inverted test-mode signal and output a second power-supply voltage.

19. The semiconductor package according to claim 18, wherein:
the first power-source selection unit includes a first transistor coupled between the first power-supply voltage and an internal power-supply voltage output terminal, and a gate of the first transistor is configured to receive the test mode signal, and
the second power-source selection unit includes a second transistor coupled between the second power-supply voltage and the internal power-supply voltage output terminal, and a gate of the second transistor is configured to receive the inverted test-mode signal.

20. A semiconductor package comprising:
a probe circuit unit configured to receive data and an address through pads;
a bump circuit unit coupled with the probe circuit unit and configured to receive data and an address through bump pads;
a power source selection unit configured to provide a first power-supply voltage to the probe circuit unit and a second power-supply voltage to the bump circuit unit,
wherein the first power-supply voltage is different from the second power-supply voltage in response to a test-mode signal received by the power source selection unit.
